(19) United States
(12) Patent Application Publication
(10) Pub. No.: US 2007/0204792 A1
(43) Pub. Date: Sep. 6, 2007

(54) Vaporizer with Integral Diaphragm

(75) Inventor: Won Gu Kang, Daejeon (KR)

Correspondence Address: SANTANGELO LAW OFFICES, P.C., 125 SOUTH HOWES, THIRD FLOOR, FORT COLLINS, CO, 80521, US

(73) Assignee: SEBINE TECHNOLOGY, INC., Daejeon (KR)

(21) Appl. No.: 10/599,766

(22) PCT Filed: Apr. 8, 2005
(86) PCT No.: PCT/KR05/01013

§ 371 Date: Oct. 6, 2006

(30) Foreign Application Priority Data
Apr. 8, 2004 (KR) 10-2004-0023988
Jul. 13, 2004 (KR) 10-2004-0054337

(51) Int. Cl. H01L 21/205

(52) U.S. Cl. 118/302; 118/300

(57) ABSTRACT

As described above, the present invention relates to a vaporizer integral with a diaphragm, the vaporizer comprising: a liquid source supplying part 10; a vaporizing part 30; a recess 16; a O-ring 17; said liquid source supplying part including a source intaking passage 11 for receiving a liquid source, an intaking tube 12 communicated with the source intaking passage 11 and having a fine hole 12a formed thereon, a stopper 13 formed on a place at which the source intaking passage 11 and the intaking tube 12 are joined together, an adjusting pin 14 for controlling supplying of the liquid source from the source intaking passage 11 to the intaking tube 12, and a diaphragm 15 integral with the adjusting pin 14; said vaporizing part 30 including a first heater 31 attached to a body of the vaporizing part 30 to heat the vaporizing part, a vaporizing chamber 35 for vaporizing the liquid source, a gas transporting passage 37 for supplying a transporting gas, and a discharging port 38 for communicating with the vaporizing chamber 35 and for discharging the transporting gas and the vaporized liquid source to the outside of the vaporizing chamber 35, and said recess 16 being formed on selected one of the liquid source supplying part 10 and the vaporizing part 30 to minimize a thermal contact area therebetween, and coupled with the O-ring 17.

### TECHNICAL FIELD

The present invention relates to a vaporizer with integral diaphragm, and more particularly, a vaporizer with integral diaphragm which produces a gas needed for a semiconductor device fabricating process from a liquid source.

### BACKGROUND OF ART

Generally, in a semiconductor device fabricating process, a desired semiconductor device is fabricated through repetition of a film growing process such as epitaxial process and deposition process, and a pattern etching process to a semiconductor wafer. Above all, a criterion for the film growing process become severe more and more as the semiconductor device is to be denser and more integrated.

For example, a very thin film such as an insulating film for a capacitor or gate is required. Further, an electrode film or a wiring layer is required to be thin. For example, a method for forming the wiring layer was proposed, in which an copper film or an aluminum film is grown by using CVD (Chemical Vapor Deposition) method. In this case, a gas is vaporized from a liquid source so as to grow a film and used in the film growing process. The liquid source is vaporized by a vaporizer to produce a gas for making a film. In a conventional film growing process, a flow rate of the liquid source is very low.

Therefore, for performing a film with high accuracy, a liquid source supplied to a vaporizer should be effectively vaporized, and thus vaporized gas source is supplied to a downstream of a film growing apparatus.

Hereafter, a conventional vaporizer will be described with reference to FIG. 1.

As will be seen from FIG. 1, a vaporizer 200 comprises: a source suction passage 231 for receiving a liquid source from an outside; a vaporizing chamber 235 for vaporizing the received liquid source; a gas transporting passage 232 for receiving a transporting gas supplied for transporting a vaporized liquid source; a discharging port 238 for discharging the vaporized liquid source and the transporting gas from the vaporizing chamber 235; a vaporizing part 230 having a heater 234 for heating the vaporizing chamber 235; an adjusting part 210, positioned on the top end of the vaporizing part 230, for adjusting the amount of flow of the liquid source incoming into the vaporizing part 230; and an actuator 250 for controlling the adjusting part 210.

In such constructed vaporizer 200, as the body of the vaporizer is heated by the heater 234 at all times, and the portion to which the liquid source is supplied is also heated by the conducted heat, there is occurred a problem that the source can be metamorphosed and, in an acute case, can be decomposed. Further, there can be one other problem that the transporting gas 232 from the gas transporting passage 232 is not heated enough and flowed into the vaporizing chamber 235 to make variation of pressure and to flow backward to the gas transporting passage 232. Furthermore, there can be another problem that the vaporizer 200 is not constructed to heat the vaporizing chamber 235 concentratively, and the liquid source can not be vaporized effectively.

### DISCLOSURE OF INVENTION

Therefore, the present invention is devised to overcome the above mentioned problems, and an object of the present invention is a vaporizer with an integral diaphragm, having a simple passage for passing a liquid source, which prevents a space for a transported liquid source from being heated to prevent a deformation of the liquid source, make a transporting gas, supplied through a gas transporting passage in a vaporizing part, be heated enough, and prevents flowing backward of the transporting gas, or the transporting gas from flowed into the gas transporting passage.

### BRIEF DESCRIPTION OF THE DRAWINGS

The above objects, other features and advantages of the present invention will become more apparent by describing the preferred embodiment thereof with reference to the accompanying drawings, in which:

FIG. 1 is a schematic diagram showing a vaporizer according to a prior art;

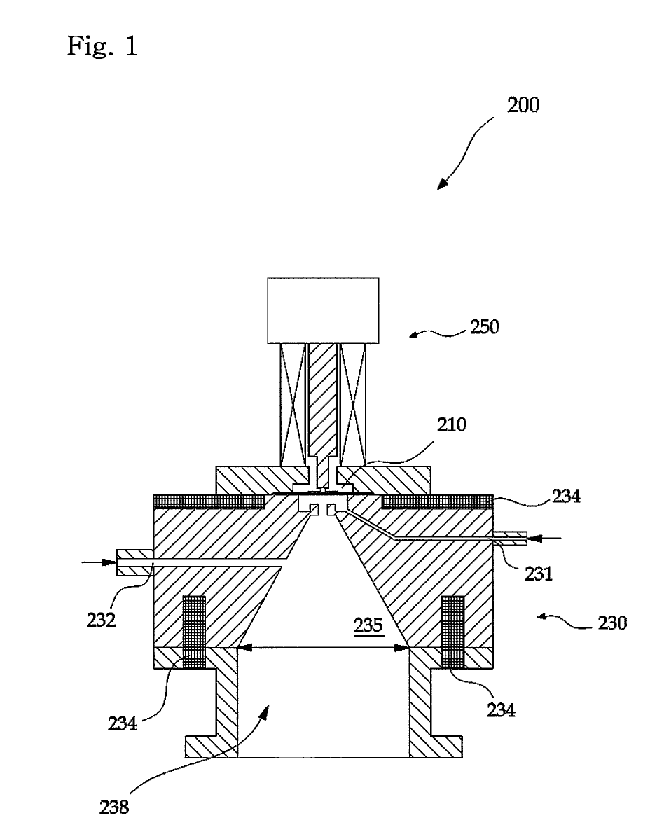

FIG. 2 is a schematic diagram showing a vaporizer according to the present invention;

FIG. 3 is a schematic diagram showing an assembled vaporizer according to the present invention; and

FIG. 4 is a schematic diagram showing a vaporizer with a heater block the lower end thereof according to the present invention.

*Brief description of reference number*

| | |
|---|---|
| 10: Liquid source supplying part | 11, 231: Source intaking passage |
| 12: Intaking tube | 12a: Fine hole |
| 13: Stopper | 14: Adjusting pin |
| 15: Diaphragm | 16: Recess |
| 17: O-ring | 18: Cooling device |
| 30, 230: Vaporizing part | 31: First heater |
| 32: Second heater | 33: Temperature sensor |
| 35, 235: Vaporizing chamber | 36: Gap |
| 37, 232: Gas transporting passage | 38, 238: Discharging port |
| 50, 250: Actuator | 57: Heater block |
| 100: Vaporizer integral with diaphragm | 200: Vaporizer |
| 210: Adjusting part | 234: Heater |

### BEST MODE FOR CARRYING OUT THE INVENTION

Reference will now be made in detail to preferred embodiments of the present invention, examples of which are illustrated in the accompanying drawings.

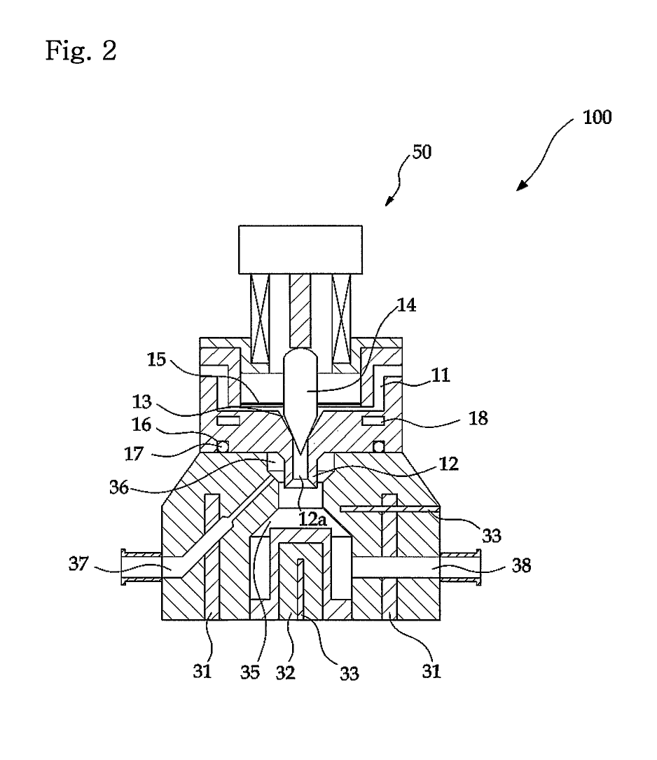

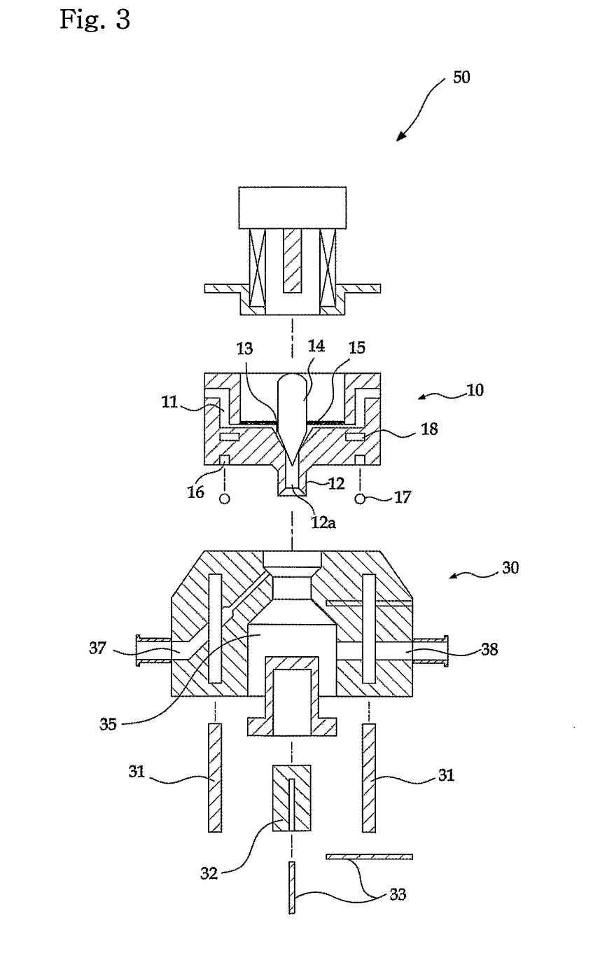

FIG. 2 is a schematic diagram showing a vaporizer according to the present invention, and FIG. 3 is a schematic diagram showing an assembled vaporizer according to the present invention.

As shown in Figs., a vaporizer according to the present invention is comprised of: a vaporizing part 30 for vaporizing a liquid source; a liquid source supplying part 10 for receiving the liquid source from outside and selectively supplying the received liquid source to the vaporizing part 40 by controlling the flow of the liquid source; and an actuator 50 for controlling the liquid source supplying part 10.

The liquid source supplying part 10 includes: a source intaking passage 11 for receiving the liquid source from outside; an intaking tube 12 communicated with the source intaking passage 11 and having a fine hole 12a for supplying the intaked liquid source to a vaporizing chamber 35; a stopper 13 formed on a portion at which the source intaking passage 11 and the intaking tube 12 are joined together; an adjusting pin 14 which is operated by the actuator 50 to control supply of the liquid source by contacting and detaching the pin to and from the stopper 13 repeatedly; a diaphragm 15 which is integrally attached to the adjusting pin 14 in order to impart elasticity to the adjusting pin 14 such that the adjusting pin 14 is operated with the actuator 50 to repeat up and down oscillation; a built-in cooling device 18 for making the liquid source hold a low temperature in the liquid source supplying part 10; a recess 16 which is formed on a side contacted with the vaporizing part 30 in order to decrease the heat transmitted from the vaporizing part and to shut the inside of the vaporizer 100 from the outside; and a O-ring 17 sat on a position corresponding to the recess 16.

The lower surface of the diaphragm is formed as a part of a supplying line for the liquid source formed by the source intaking passage 11. In one other embodiment, the lower surface of the diaphragm is separated from the supplying line for the liquid source formed by the source intaking passgage 11 to operate independently.

In here, one end of the adjusting pin 14 is shaped as a cone, and the stopper is formed to have a corresponding opposite shape.

However, it is preferable that a tilt angle of the one end of the adjusting pin 14 is slightly smaller than that of the stopper 13 to control a flow of the liquid source fine.

The diaphragm 15 is acted not only to impart elasticity to the adjusting pin 14, but also to prevent the liquid source from being flowed backward to the liquid source supplying part 10. Therefore, a separate elastic means such as a spring and the space for receiving the elastic means are not needed in order to give the elasticity to the adjusting pin 14.

At the same time, in installing the built-in cooling device 18 in the embodiment, the cooling device 18 is installed in the liquid source supplying part 10, but is not limited to this. The cooling device 18 can be rather installed outside of the liquid source supplying part 10.

Further, the recess 16 formed on the liquid source supplying part 10 and the O-ring can be formed on the vaporizing part 30 as far as it is not deviated from the object of the present invention that a thermal contact area for the liquid source supplying part 10 and the vaporizing part 30 is low, and the inside is shut from the outside.

As described above, the recess 16 is formed on the one selected from the liquid source supplying part 10 and the vaporizing part 30 in order to minimize the thermal contact area, and the O-ring 17 is inserted into the recess 16.

The vaporizing part 30 is comprised of: a vaporizing chamber 35 which has a space extended downwardly in order to the liquid source in order to vaporize the liquid source ejected from the fine hole 12a of the liquid source supplying part 30; a gas transporting passage 37 for supplying the vaporizing chamber 35 with the transporting gas which transports the vaporized liquid source in the vaporizing chamber 35; a discharging port 38 for discharging the transporting gas and the vaporized liquid source to the outside; a first heater 31 which is positioned the place at which the gas transporting passage 37 and the discharging port 38 are formed to heat the vaporizing part 30 so as to vaporize the liquid source, and to heat the gas transporting passage 37 and the discharging port 38 at the same time so that the liquid source, vaporized and discharged with the transporting gas, can maintain a stable state; a second heater 33 which is protruded into the inside of the vaporizing chamber 35 in order to heat the vaporizing chamber 35 in concentrative; and a temperature sensor 33 integral with the first and the second heaters 31 and 32.

Herein, the gas transporting passage 37 is inclined to increase a thermal contact area so that the transported gas is heated enough by the vaporizing part 30. And, when the gas transporting passage 37 is communicated with the vaporizing chamber 35, the intaking tube 12 is projected into the vaporizing chamber 35 formed on the top end of the liquid source supplying part 10 to make a gap 36 around the intaking tube 12 and, the gas transporting passage 37 is connected the gap 36. Therefore, the transporting gas supplied from the gas transporting passage 37 is heated enough in the gap 36 to maintain pressure higher than that of a vaporizing zone in the vaporizing chamber and to prevent the transporting gas from being flow backward from the vaporizing chamber 35 when the transporting gas is flowed into the vaporizing chamber 35. At the same time, the liquid source which is supplied to the vaporizing chamber 35 through the fine hole 12a of the intaking tube 12 is prevented from being flowed into the gas transporting passage 37.

The actuator according to the present invention may be either a manual actuator or a Piezo actuator.

The operation and principle for the present invention will described in detail below.

Referring to FIGS. 2 and 3, a liquid source is flowed in through the source intaking passage 11 from the outside, and transported to the stopper 13. The transported liquid source is controlled the adjusting pin 14 which is selectively in contact with the stopper 13.

The principle in which the adjusting pin 14 controlled by the actuator 50 controls the liquid source in the stopper 13 is as follows.

When the actuator 50, either a manual actuator or Piezo actuator, is operated, the adjusting pin 14 in the liquid source supplying part 10 is also operated.

The adjusting pin 14 is moved down by a falling force of a motional means 53 when moving down the adjusting pin 14, and is moved up by the dynamic stability of the diaphragm 15. In actual, the adjusting means repeats the moving-up and moving-down, and the moving-up and down is possible by means of elasticity of the diaphragm 15.

That is, the diaphragm 15 is acted as an elasticity means for moving up and down the adjusting means 14 repetitively.

In addition, the diaphragm 15 is also acted to prevent the liquid source from flowing backward to the upstream of the diaphragm 15.

As described above, the moving-up and -down of the adjusting pin 14 makes a gap between the adjusting pin 14 and the stopper 13 to pass the liquid source, thus acting as a valve through the moving-up and -down.

Herein, methods for contacting the adjusting pin 14 to the stopper 13 and detaching the adjusting pin from the stopper are as follows.

One is such that spacing between the adjusting pin 14 and the stopper 13 is held in normal state, and the adjusting pin 14 is moved down together with the actuator 50 to be in contact with the stopper and is moved up by the elasticity of the diaphragm 15 to be apart from the stopper 13 when the motional means 53 is moved up. The other is such that the adjusting pin 14 is in contact with the stopper 13 in normal state, and is moved up by the elasticity of the diaphragm 15 when the actuator 50 is moved up.

Further, as the tilt angle of the adjusting pin 14 is formed smaller than that of the stopper 13 to have the adjusting pin and the stopper hold different angles, the supplying of the liquid source is entirely blocked when the adjusting pin 14 is moved down to be in contact with the stopper 13.

And, the liquid source is cooled enough by the cooling device 18 to the chemical reaction and deformation caused by the heat transferred from the vaporizing part 30 when the liquid source is in the liquid source supplying part 10.

Meanwhile, the liquid source on the stopper 13 is moved to the fine hole 12a in the inside of the intaking tube 12 protruding into the vaporizing chamber 35 through the controlling of the adjusting pin 14, is injected in the vaporizing chamber 35 through the fine hole 12a and is heated enough to be vaporized by the second heater 32 which is formed to protrude in the vaporizing chamber 35.

At the same time, the transporting gas for transporting the liquid source is flowed into the vaporizing chamber 35 by means of the gas transporting passage 37. The transporting gas passing through the gas transporting passage 37 is heated enough by the first heater 31, as the gas transporting passage 37 is formed to be inclined.

And, the gas transporting passage 37 is communicated with the gap 36 which is formed between the upper inner circumference of the vaporizing chamber 35 and the intaking tube 12 of the liquid source supplying part 10, and the transporting gas from the gas transporting passage 37 is heated enough in the gap 36 to flow to the vaporizing chamber 35, but not to flow backward.

Through the above processes, the liquid source vaporized in the vaporizing chamber 35 is discharged by the transporting gas to the discharging port 38. At this time, the transporting gas and the vaporized liquid source are continuously heated by the first heater 31 formed in the vaporizing part 30.

Further, the first and the second heaters 31 and 32 include a temperature sensor 33 which senses a temperature for an area around the first and second heaters 31 and 32 in real time to increase response to a variation of temperature.

Therefore, portions of the inside of the vaporizing chamber 30 can properly maintain a temperature.

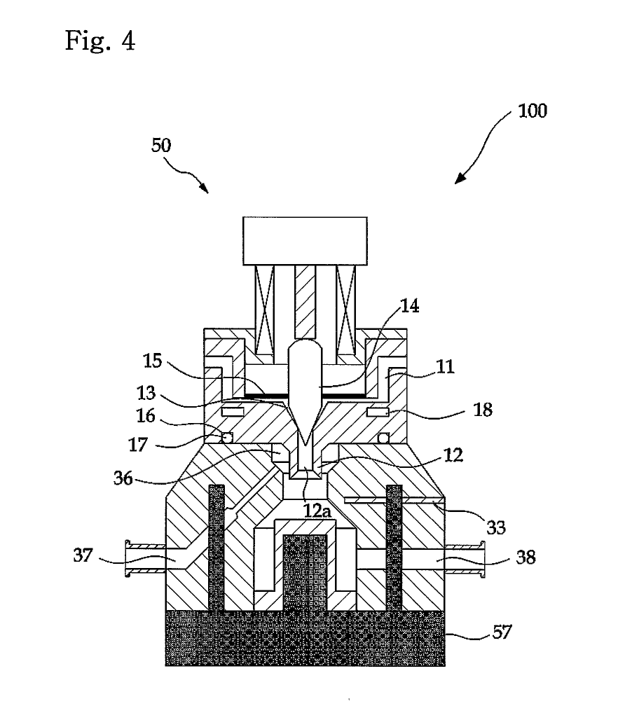

FIG. 4 is a schematic diagram showing a vaporizer with a heater block the lower end thereof according to the present invention. In the figure, the first and the second heaters 31 and 32 are unified as one heat block 57, rather than separated, and installed in the lower end of the vaporizing part 30. At this time, the heater block 52 is to have a shape that a column rests on a flat to protrude in order for the second heater 32, projecting into the inside of the vaporizing chamber 35, to perform its role. Furthermore, a column can be added in order for the first heater 31 to perform its role.

### INDUSTRIAL APPLICABILITY

With the above description, according to the present invention, there are lots of effects that deformation of an liquid source caused by heating of a vaporizing space is prevented as a liquid source supplying part for transporting the liquid source and a vaporizing part having a vaporizing chamber heated by a heater are thermally separated from each other, the liquid source is prevented from flowing into a gas transporting passage as a gap is provided to induce a pressure difference in the passage in which the liquid source is flowed, the liquid source flowed in the vaporizing chamber is rapidly vaporized as the liquid source is heated in concentrative by a heater projecting into the center of the vaporizing chamber, and the transporting gas is prevented from flowing backward as the transporting gas in the gas transporting passage is heated enough.

Further, there are effects that the structure of the present invention is simple as an adjusting pin and a diaphragm is formed as one body and the diaphragm is acted as a elasticity means, and a loss of liquid source is reduced as an inner space of a passage for the liquid source.

1. A semiconductor fabrication vaporizer comprising:
a liquid source;
a vaporizing part; and
an O-ring positioned on a place in which the liquid source part and the vaporizing part are in contact with each other and minimize a thermal contact area between the liquid source part and the vaporizing part.

2. A semiconductor fabrication vaporizer comprising:
a liquid source part;
a vaporizing part;
a recess;
an O-ring;
said liquid source part including a source intake passage, an intake tube communicated with the source intake passage and having a fine hole formed thereon, a stopper surface formed on a place at which the source intake passage and the intake tube are joined together, an adjusting pin to control a liquid at a location between the source intake passage and the intake tube, and a diaphragm integral with the adjusting pin;
said vaporizing part having a body and including a first heater attached to the body of the vaporizing part, a vaporizing chamber, a gas transport passage, and a discharge port communicating with the vaporizing chamber to discharge a transported gas to an area outside of the vaporizing chamber, and
said recess being formed on a selected one of the liquid source part or the vaporizing part to minimize a thermal contact area therebetween.

3. The semiconductor fabrication vaporizer as claimed in claim 2, wherein the diaghram has a lower surface and wherein the lower surface of the diaphragm is formed as a part of a supply line for the liquid source and is formed by the source intake passage.

4. The semiconductor fabrication vaporizer as claimed in claim 2, wherein the diaghram has a lower surface and wherein the lower surface of the diaphragm is separated from a supply line for the liquid source and is formed by the source intake passage.

5. The semiconductor fabrication vaporizer as claimed in claim 2, wherein the adjusting pin has an upper side and further comprising an actuator adjacent to the upper side of the adjusting pin, and wherein the adjusting pin is operated by the actuator.

6. The semiconductor fabrication vaporizer as claimed in claim 2, wherein the vaporizing part further comprises a second heater, the second heater being formed to protrude into the vaporizing chamber.

7. The semiconductor fabrication vaporizer as claimed in claim 1, and further comprising an adjusting pin to control a liquid source, having at least one end, and a stopper surface, and wherein one end of the adjusting pin is inclined at an first inclined angle and the stopper has an inclined part having a second inclined angle, and wherein the first inclined angle of the adjusting pin is smaller than the second inclined angle of the stopper surface.

8. The semiconductor fabrication vaporizer as claimed in claim 2, wherein the vaporizing chamber has an upper inner circumference, and wherein the gas transport passage is communicated with a gap formed between the upper inner circumference of the vaporizing chamber and the intake tube of the liquid source part.

9. The semiconductor fabrication vaporizer as claimed in claim 6, wherein the first and the second heaters include a temperature sensor to sense a temperature of a region between the first heater and the second heater in real time.

10. The semiconductor fabrication vaporizer as claimed in claim 6, wherein the first heater and the second heater are unified to form a heater block.

11. The semiconductor fabrication vaporizer as claimed in claim 2, wherein the liquid source part further includes a cooling device to cool heat transferred from the vaporizing chamber.

12. The semiconductor fabrication vaporizer as claimed in claim 5, wherein the actuator is any one selected from a manual actuator or a piezo actuator.

13. The semiconductor fabrication vaporizer as claimed in claim 2, wherein the gas transport passage is inclined to increase a thermal contact area with the vaporizing.
